(19) United States
(12) Patent Application Publication
(10) Pub. No.: US 2017/0279597 A1
(43) Pub. Date: Sep. 28, 2017

(54) SYSTEMS AND METHODS FOR FAST LOCAL OSCILLATOR PHASE FLIP

(71) Applicant: QUALCOMM Incorporated, San Diego, CA (US)

(72) Inventors: Hyunsik Park, San Jose, CA (US); Jeongsik Yang, San Jose, CA (US)

(21) Appl. No.: 15/081,615

(22) Filed: Mar. 25, 2016

(51) Int. Cl. H04L 7/033; H03L 7/18

(52) U.S. Cl. CPC H04L 7/033; H03L 7/1803

(57) ABSTRACT

Methods, systems, and devices for wireless communication are described. An internal state of a frequency divider of a local oscillator (LO) may be stored using a storage device in order to facilitate phase flipping of one or more signals output by the LO. The frequency divider may also include a pulse swallower that swallows a pulse of a signal input into the frequency divider. Using one or more power supply cutting switches in combination with a storage device and pulse swallower, high speed and reliable phase flipping of LO signals may be performed.

### BACKGROUND

Field of the Disclosure

The following relates generally to wireless communication, and more specifically to fast systems and methods for fast local oscillator phase flipping.

Description of Related Art

Wireless communications systems are widely deployed to provide various types of communication content in packets such as voice, video, data packets, messaging, broadcast, and so on. These systems are often multiple-access systems capable of supporting communication with multiple users by sharing the available system resources (e.g., time, frequency, and power). Wireless Local Area Networks (WLAN) are an example of such systems and are widely deployed and used. Other examples of such multiple-access systems may include code-division multiple access (CDMA) systems, time-division multiple access (TDMA) systems, frequency-division multiple access (FDMA) systems, and orthogonal frequency-division multiple access (OFDMA) systems.

When transmitting or receiving packets, a wireless device utilizes one or more oscillating signals generated by a local oscillator. The oscillating signals are often used during upconversion and downconversion. For instance, during reception, an oscillating signal is used to downconvert a received signal from a radio frequency to an intermediate frequency (super-heterodyne) or a baseband frequency (direct conversion). During transmission, an oscillating signal is used to upconvert a transmission signal from a baseband frequency to an intermediate frequency or a radio frequency.

A local oscillator is capable of generating multiple signals depending on received input signal(s). When generating multiple signals, the local oscillator typically generates signals having similar frequency and amplitude characteristics which are phase shifted with respect to each other. These signals are then used during reception (e.g., to process a received signal) or transmission (e.g., to generate a transmission signal). As such, it is important that the phase of the local oscillator signals be consistent and/or maintained in order to properly generate a transmitting signal or process a received signal. In some cases (e.g., in beamforming and/or when switching communication modes), however, the signals generated by the local oscillator may be misaligned (e.g., out of phase based at least in part on an expected output phase) due to the initial state of a frequency divider of the local oscillator or glitches in a reference signal (e.g., a clock signal input to the local oscillator or a direct current power supply used to generate a control signal as an input to the local oscillator).

### SUMMARY

Techniques for flipping the phase of a local oscillator signal are described. Depending on the initial state of a frequency divider of the local oscillator and/or changes or glitches in a control signal, the phase of a output signal of the local oscillator may be misaligned with respect to an expected phase (e.g., the phase of the output signal may be shifted from an expected output phase by 180 degrees). Flipping the output signal may align the phase of the output signal with an expected phase. However, in per-packet mode switching or during a beamforming operation, for example, the time allocated for flipping the output signal may be limited and in some cases, the time allocated may be as little as 300 nanoseconds (ns). Therefore, the techniques for flipping the phase of a local oscillator signal described in the present disclosure may allow for proper detection of a phase misalignment and high-speed output signal flipping in order to properly align one or more output signals of a local oscillator.

A method of wireless communication includes inputting an oscillator signal into a frequency divider, storing a state of the frequency divider, and outputting a phase shifted version of the oscillator signal based at least in part on the stored state of the frequency divider.

A device for wireless communication includes means for inputting an oscillator signal into a frequency divider, means for storing a state of the frequency divider, and means for outputting a phase shifted version of the oscillator signal based at least in part on the stored state of the frequency divider.

A device for wireless communication includes an oscillator, a frequency divider, and a storage device. The frequency divider is configured to receive an oscillator signal from the local oscillator, and the storage device is configured to store a state of the frequency divider. The frequency divider is further configured to output a phase shifted version of the oscillator signal based at least in part on the stored state of the frequency divider.

A non-transitory computer readable medium for wireless communication is described. The non-transitory computer-readable medium may include instructions to cause a processor to input an oscillator signal into a frequency divider, store a state of the frequency divider and output a phase shifted version of the oscillator signal based at least in part on the stored state of the frequency divider.

The method, device, or non-transitory computer-readable medium described above may further include processes, features, means, or instructions for swallowing a pulse of the oscillator signal. The pulse may be a current pulse. Outputting the phase shifted version of the oscillator signal is based at least in part on the swallowed pulse. Swallowing the pulse of the oscillator signal includes swallowing a current pulse of the oscillator signal after inputting the oscillator signal into the frequency divider. The current pulse may be swallowed by activating a current pulse swallow switch using a flip or flipb signal synchronized with the oscillator signal.

In some cases, storing the state of the frequency divider includes delaying decay of the state of the frequency divider. Delaying the decay of the state may use at least one selected from the group consisting of a switchable capacitor bank, a switchable resistor bank, and a cutting switch connected to an input of the frequency divider. The selected components can be activated using a flip signal. Storing the state of the frequency divider can include maintaining the state of the frequency divider until a next frequency division, for example, by activating a cutting switch connected to an input of the frequency divider, activating a cutting switch connected to a power supply, or activating a switchable capacitor bank. The cutting switch or the switchable capacitor bank may be activated using a flip or flipb signal.

The frequency divider may be coupled to a local oscillator configured to generate the oscillator signal. In some cases, the frequency divider is a current mode divider.

In some examples, switching from a first wireless communication mode to a second wireless communication mode occurs. In such examples, the internal state of the frequency divider may be preserved prior to switching between the first and second wireless communication modes. The preserved internal state of the frequency divider is then restored after switching between the first and second wireless communication modes.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 illustrates an example of a wireless local area network (WLAN) that supports fast local oscillator phase in accordance with aspects of the present disclosure;

FIG. 2 illustrates an example of a wireless communications device such as a station (STA) or access point (AP), that supports fast local oscillator phase flipping in accordance with aspects of the present disclosure;

FIG. 3 illustrates an example of a wireless communications device, such as a STA or an AP, that supports fast local oscillator phase flipping in accordance with aspects of the present disclosure;

FIGS. 4A and 4B illustrate example circuit diagrams of a local oscillator frequency divider that supports fast local oscillator frequency divider output phase flipping in accordance with aspects of the present disclosure;

FIG. 5 illustrates a block diagram of an example of a wireless device, such as a STA or AP, that supports fast local oscillator phase flipping in accordance with aspects of the present disclosure;

FIG. 6 illustrates a method for fast local oscillator frequency divider phase flipping in accordance with aspects of the present disclosure.

### DETAILED DESCRIPTION

According to the present disclosure, a communication device, such as a wireless station (STA) or an access point (AP), utilizes local oscillator signal phase flipping techniques. Aspects of the disclosure are described in the context of a STA or an AP in a wireless local area network (WLAN). For example, an AP that is transmitting a signal to a STA utilizes methods for fast local oscillator phase flipping techniques and the STA can use similar techniques when processing the signal received from the AP. The STA can also utilize methods for fast local oscillator phase flipping techniques when transmitting a signal to an AP, while the AP uses similar techniques when processing the signal received from the STA.

In one example, a local oscillator of the AP includes an oscillator (e.g., a voltage controlled oscillator (VCO)), a frequency divider, a storage device, a pulse swallower, and a flip signal generator. The oscillator generates an oscillating signal to be used as input to the frequency divider. The oscillator can be controlled by a control signal (e.g., a clock signal generated by another oscillator, an alternating current (AC) signal, or a direct current (DC) signal from a power supply).

The frequency divider is configured to generate four oscillating signals (In-phase positive (Ip), In-phase negative (In), Quadrature positive (Qp), and Quadrature negative (Qn)), each of which are out of phase (e.g., 90 degree phase difference) with respect to one another. These signals are output from the local oscillator and used by a wireless device during transmission and reception (e.g., when downconverting or upconverting a signal). The storage device is configured to store the internal state (e.g., the internal values for Ip, In, Qp, and Qn) of the frequency divider and includes circuitry to delay the decay of the internal state of the frequency divider or maintain or preserve the internal state of the frequency divider while the divider input is disconnected. In some cases, the internal state of the frequency divider is stored until a next frequency division where the internal state of the frequency divider can be restored prior to performing the next frequency division. For example, the storage device includes a switchable capacitor bank or a switchable resistor bank configured to delay the decay of the internal states of the frequency divider.

The pulse swallower is configured to swallow a pulse of an oscillating signal after being input into the frequency divider. By swallowing a pulse of the oscillating signal, a rising edge (or falling edge) of the oscillating signal input to the frequency divider is delayed ensuring that the internal state of the frequency divider is restored prior to the next frequency division. The flip signal generator generates a flip signal that triggers (i.e., activates or deactivates) the storage device and/or the pulse swallower. The flip signal may be synchronized with the oscillating signal input into the frequency divider.

Using one or more of the storage device, the pulse swallower, and the flip signal generator as discussed herein, the signal(s) output from the frequency divider of the local oscillator can be flipped (e.g., inverted 180 degrees) in order to align the phase of the signal(s) with an expected output phase. Aspects of the disclosure are further illustrated by and described with reference to device diagrams, system diagrams, and flowcharts that relate to fast local oscillator phase flipping.

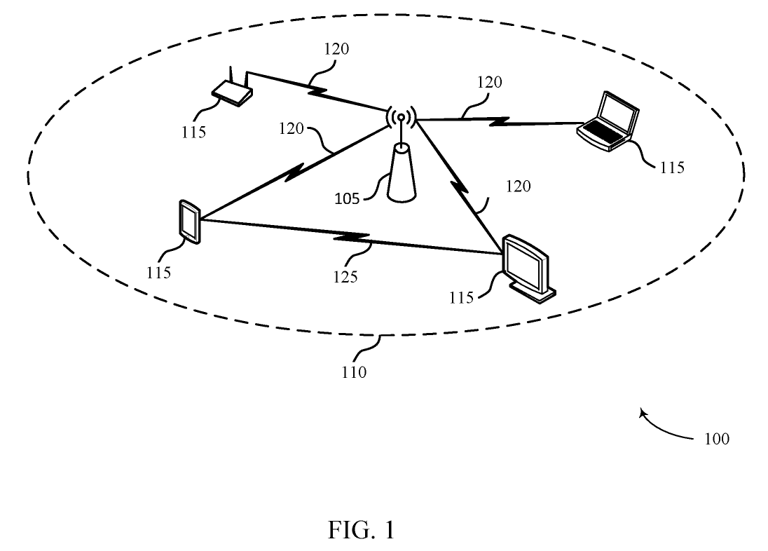

FIG. 1 illustrates a wireless local area network (WLAN) 100 (e.g., a Wi-Fi network) configured in accordance with various aspects of the present disclosure. In the present example, the WLAN 100 includes an AP 105 and multiple STAs 115. The STAs 115 can be mobile stations, smartphones, tablets, laptops, personal digital assistants (PDAs), other handheld devices, netbooks, notebook computers, display devices (e.g., TVs, computer monitors, etc.), printers, etc. While only one AP 105 is illustrated, the WLAN 100 may have multiple APs 105. The STAs 115 can also be referred to as mobile stations (MSs), mobile devices, access terminals (ATs), user equipment (UE), subscriber stations (SSs), or subscriber units. The STAs 115 associate and communicate with the AP 105 via a communication link 120. The AP 105 has a geographic coverage area 110 such that STAs 115 within that geographic coverage area 110 are within range of the AP 105. The STAs 115 are dispersed throughout the geographic coverage area 110. Each STA 115 can be stationary or mobile.

Although not shown in FIG. 1, a STA 115 can be covered by more than one AP 105 and can therefore associate with one or more APs 105 at different times. A single AP 105 and an associated set of STAs 115 are referred to as a basic service set (BSS). An extended service set (ESS) is a set of connected BSSs. A distribution system (DS) (not shown) is used to connect APs 105 in an ESS. A geographic coverage area 110 for an AP 105 can be divided into sectors making up only a portion of the coverage area (not shown). The WLAN 100 includes APs 105 of different types (e.g., metropolitan area, home network, etc.), with varying sizes of coverage areas and overlapping coverage areas for different technologies. Although not shown, other wireless devices can communicate with the AP 105.

While the STAs 115 are capable of communicating with each other through the AP 105 using communication links 120, STAs 115 can also communicate with each other via direct wireless communication links 125. Direct wireless communication links 125 can occur between STAs 115 regardless of whether any of the STAs 115 is connected to AP 105. Examples of direct wireless communication links 125 include Wi-Fi Direct connections, connections established by using a Wi-Fi Tunneled Direct Link Setup (TDLS) link, and other peer-to-peer (P2P) group connections. The STAs 115 and APs 105 shown in FIG. 1 communicate according to the WLAN radio and baseband protocol including physical (PHY) and medium access control (MAC) layers from IEEE 802.11, and its various versions including, but not limited to, 802.11b, 802.11g, 802.11a, 802.11n, 802.11ac, 802.11ad, 802.11ah, 802.11z, etc. In other implementations, peer-to-peer connections or ad hoc networks may be implemented within WLAN 100.

In some cases, a STA 115 or AP 105 operates in a shared or unlicensed frequency spectrum. These devices perform a clear channel assessment (CCA) prior to communicating to determine whether the channel is available. A CCA may include an energy detection procedure to determine whether there are any other active transmissions. For example, the device may infer that a change in a received signal strength indication (RSSI) of a power meter indicates that a channel is occupied. Specifically, signal power that is concentrated in a certain bandwidth and exceeds a predetermined noise floor may indicate another wireless transmitter. A CCA may also include detection of specific sequences that indicate use of the channel (e.g., preambles transmitted by other devices).

A beamforming process can be performed by wireless devices in communication with each other. When performing beamforming during transmission, a wireless device, such as AP 105 or STA 115, uses multiple antennas in an antenna array to transmit signals. The signals transmitted by each of the antennas are phase shifted with respect to one another such that when the signal is transmitted, constructive and destructive interference between the signals occurs at specific locations from the transmitting device.

For example, an AP 105 can use multiple antennas to transmit signals to a STA 115 in a beamforming process. A signal for each of the multiple antennas may be generated by the AP 105 and the signal may be processed such that each signal, or at least one signal, of the multiple signals is phase shifted with respect to the other signals. To transmit the signals to the STA 115, the AP 105 uses the multiple antennas of the antenna array to transmit multiple signals toward the STA 115. In this manner, the multiple signals are generated, processed, and transmitted such that constructive interference between the multiple transmitted signals occurs at the location of the STA 115.

During reception in a beamforming process, the STA 115 includes multiple antennas, each of which receives at least one of the multiple signals transmitted by the AP 105 to the STA 115. Using signal processing (e.g., temporal and spatial filtering), the STA 115 processes the signals received by the multiple antennas in order to decode the transmitted signals. The transmission and reception processes each involve using one or more signals generated by a local oscillator in order to generate the signal(s) to be transmitted or process the received signal(s). As such, if phases of the one or more signals generated by the local oscillator are misaligned (e.g., due to an initial state of a frequency divider of the local oscillator), issues could arise resulting in improper or inefficient transmission and/or reception of one or more signals.

As shown, the AP 105 and STAs 115 support local oscillator signal phase flipping in accordance with various aspects of the present disclosure. To generate a signal to be transmitted to the STA 115, the AP 105 processes digital packets by converting the digital packets into an analog signal using filters, amplifiers, buffers, multiplexers, oscillators, etc. When upconverting the analog signal, e.g., from a baseband frequency to a radio frequency, an AP 105 uses a signal generated by a local oscillator. Similarly, when downconverting a received signal, e.g., a signal received by STA 115, the STA 115 uses a signal generated by a local oscillator. Due to the internal states of a frequency divider within a local oscillator, the signals generated by the local oscillator can be misaligned with an expected output phase. This can occur, for example, when a wireless device (e.g., AP 105 or STA 115) switches wireless communication modes (e.g., from a wireless communication mode configured to support 160 megahertz (MHz) channel width to a wireless communication mode configured to support 80 MHz channel width) or when a wireless device switches from transmitting to receiving (or vice versa) and cuts power to the local oscillator not being used.

To flip (e.g., invert or phase shift) one or more signals output from the local oscillator, the local oscillator can utilize any of a pulse swallower, storage circuitry, and power supply cutting switches (or other switches) as described herein. The pulse swallower can be used to swallow a pulse of a signal (e.g., an oscillator signal) after being input into a frequency divider of the local oscillator. The storage circuitry can be used to store the internal state of the frequency divider (e.g., until a next frequency division). Cutting switches can also be used to maintain or preserve the internal state of the frequency divider of the local oscillator. By storing the internal state of the frequency divider and swallowing a pulse of an input signal to the frequency divider, the internal state of the frequency divider can be restored prior to the next frequency division and one or more signals output from the frequency divider can be flipped to align with an expected output.

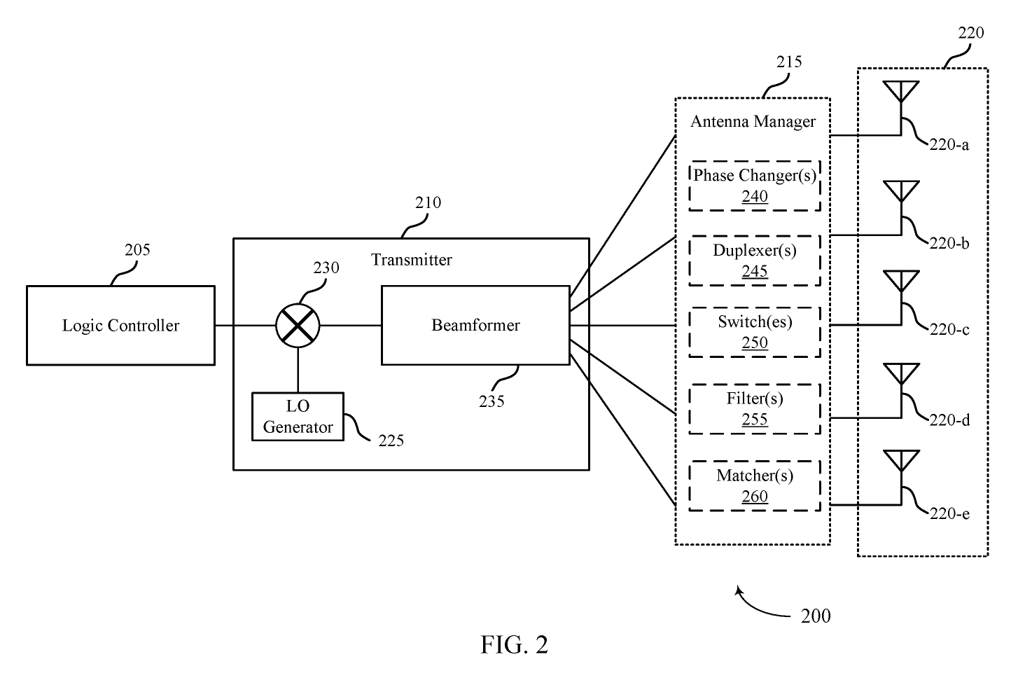

FIG. 2 illustrates one example of wireless communications device 200 that supports local oscillator signal phase flipping in accordance with various aspects of the present disclosure. Wireless communications device 200 is an example of the STA 115 or AP 105 of FIG. 1. Wireless communications device 200 includes logic controller 205, transmitter 210, antenna manager 215, and an array of antennas 220. Transmitter 210 includes a local oscillator (LO) generator 225, mixer 230, and optional beamformer 235. Antenna manager 215 includes one or more optional components such as phase changers 240, duplexers 245, switches 250, filters 255, and matchers 260. These components and other components can be included in the antenna manager 215 in order to generate transmission signals for each antenna 220 in the array. The antenna array includes five antennas 220-a, 220-b, 220-c, 220-d, and 220-e, though any number of antennas 220 may be utilized in accordance with aspects of the present disclosure.

In this example, wireless communications device 200 is capable of transmitting or receiving packets using one or more antennas 220 of the antenna array. During transmission, logic controller 205 processes one or more packets to be transmitted by the wireless communications device 200. The logic controller 205 includes circuitry to convert digital packets into analog signals which are processed by the transmitter 210. For instance, analog signals at a baseband frequency are sent from the logic controller 205 to the transmitter 210 and various components such as filters and amplifiers (not shown) can be used to process the baseband analog signals. Using mixer 230 and LO generator 225, the analog signals are modulated and upconverted to generate a modulated radio signal. If beamforming is to be performed, the modulated radio signal can then be further processed by the optional beamformer 235 which generates and routes multiple signals to each antenna in the array of antennas 220. The array of antennas 220 can then be used to shift the phase of the multiple signals, among other processes, to generate signals to be transmitted by each antenna of the array of antennas 220. Though shown separately, beamformer 235 can be included in antenna manager 215, which together process the modulated radio signal for performing beamforming using multiple antennas. In doing so, the array of antennas 220 is used as a beamforming antenna array and is configured to transmit signals that constructively and destructively interfere with each another at specific locations.

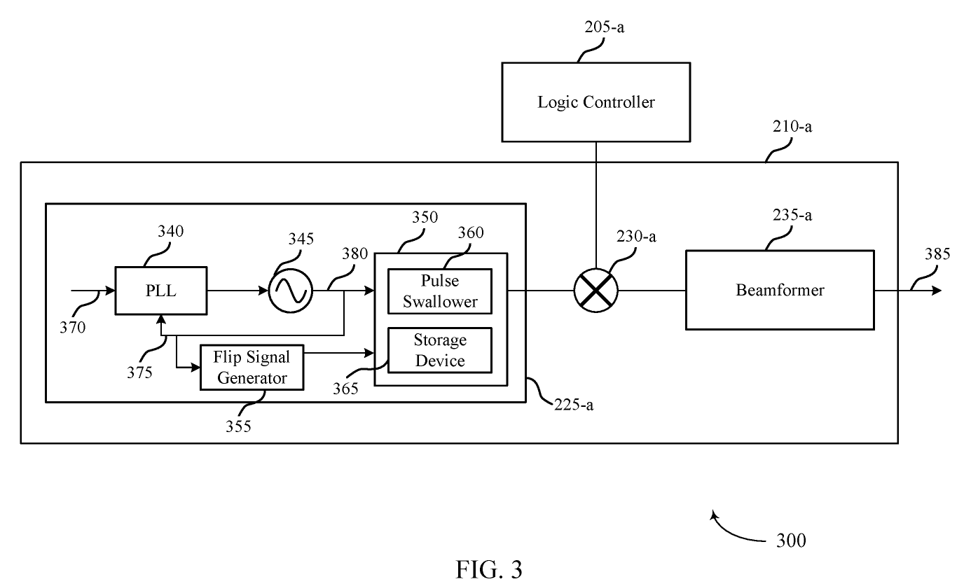

The LO generator 225 may include one or more filters, amplifiers, dividers, oscillators, etc. used to generate an LO signal used during transmission and reception. In this example, as will be described further with respect to FIG. 3, the LO generator 225 includes a storage device, a pulse swallower, and a flip signal generator, at least one of which can be used to flip one or more signals generated by the LO generator 225 in accordance with aspects of the present disclosure. To flip one or more signals generated by the LO generator 225, the pulse swallower can be used to swallow a pulse of a signal (e.g., an oscillator signal) after being input into a frequency divider of the LO generator 225. Storage circuitry and cutting switches can also be used to store the internal state of the frequency divider (e.g., until a next frequency division). By storing the internal state of the frequency divider and swallowing a pulse of an input signal to the frequency divider, the internal state of the frequency divider can be restored prior to the next frequency division and one or more signals output from LO generator 225 can be flipped in order to correct phase misalignment.

By utilizing the storage device, the pulse swallower, and the flip signal generator, among others, the LO generator 225 can produce and consistently maintain the phase of an LO signal (e.g., or a phase flipped LO signal) to be used when transmitting or receiving signals at the wireless communications device 200. Additional details related to flipping and maintaining the phase of an LO signal are presented below. The foregoing provides just one example relating to high-speed and reliable LO signal phase flipping, and the techniques of the present disclosure are not limited to the discussion of this example. For instance, in other examples, additional circuitry or devices may be utilized to generate and process transmitted and received signals.

FIG. 3 illustrates an example of wireless communications device 300 for fast local oscillator phase flipping. In some cases, wireless communications device 300 represents aspects of techniques performed by an AP 105 or a STA 115 as described with reference to FIGS. 1 and 2. As shown, wireless communications device 300 includes a logic controller 205-a, a transmitter 210-a, an LO generator 225-a, mixer 230-a, and beamformer 235-a, which represent examples of the corresponding devices described with reference to FIGS. 1 and 2.

In this example, LO generator 225-a includes a phase locked loop (PLL) 340, oscillator 345, frequency divider 350, and flip signal generator 355. The frequency divider 350 includes a pulse swallower 360 and a storage device 365. As shown, PLL 340 is controlled by control signal 370 which can be a direct current (DC) signal, an alternating current (AC) signal, or a clock signal generated by another oscillator (not shown). The PLL 340 receives a feedback signal 375 from the oscillator 345 and generates an error signal based at least in part on the phase of the feedback signal 375 and the control signal 370 to maintain phase consistency between the feedback signal 375 and the control signal 370.

Oscillator 345 may be a VCO which generates an oscillator signal 380 at a particular frequency based at least in part on the input signal from PLL 340. The frequency divider 350 divides the oscillator signal 380 and produces four signals (Ip, In, Qp, Qn), each of which are out of phase with respect to one another. For instance, the Qp and the Ip signals can have a 90 degree phase difference, the Ip and In signals can have a 180 degree phase difference, and the Qp and Qn signals can have a 180 degree phase difference. In such an example, with respect to the Ip signal, the Qp signal is 90 degrees out of phase, the In signal is 180 degrees out of phase, and the Qn signal is 270 degrees out of phase. The four signals are associated with an integer divisor (e.g., ½, ¼, etc.) of the oscillator signal 380. In some cases, frequency divider 530 is a current mode divider. Though shown as a quadrature divider (i.e., a divider that produces four signals), frequency divider 350 can produce any number of signals.

When the operating mode of the wireless communications device 300 changes, the phase of the signals output by the frequency divider 350 can be misaligned due to the initial states of the frequency divider 350 or glitches in the input oscillator signal 380. To re-align the phase of the signals output by the frequency divider 350 with expected output phases, frequency divider 350 includes a pulse swallower 360 and a storage device 365. The pulse swallower 360 includes circuitry to swallow a pulse of the oscillator signal 380. The storage device 365 includes circuitry to store the internal state of the frequency divider 350. For example, the storage device 365 can include a switchable capacitor bank that delays the decay of the internal state of the frequency divider 350. In addition, or in the alternative, the storage device 365 includes a switchable resistor bank that maintains and/or preserves the internal state of the frequency divider 350. In some cases, the internal state of the frequency divider can be stored by the storage device 365 until a next frequency division. In combination with the pulse swallower, a next frequency division can occur at the next rising edge (or falling edge) of the input signal (e.g., oscillator signal 380) to the frequency divider 350. If the pulse swallower 360 swallows a pulse of the input signal, the next frequency division can be delayed until the internal state of the frequency divider 350 is restored. For example, the internal state of the frequency divider 350 can be stored prior to switching modes and restored after switching modes.

If the signals output from the frequency divider 350 are misaligned, the flip signal generator 355 generates a flip signal that is based at least in part on the oscillator signal 380. For example, the generated flip signal can be synchronized (e.g., in phase) with the oscillator signal 380. Further, although not shown, the flip signal can also be synchronized with the control signal 370 or a signal output from the PLL 340. In some cases, the flip signal generator 355 generates a flip signal and a flipb signal, where the flipb signal is an inverted version of the flip signal. The flip signal or the flipb signal can be input into the frequency divider 350 and used to activate the pulse swallower 360 and/or the storage device 365 in order to swallow a pulse of an input signal to the frequency divider 350 and store the internal state of the frequency divider 350.

Thereafter, one or more of the signals output by the frequency divider 350 (and consequently, the LO generator 225-a) are input into mixer 230-a along with an analog signal from logic controller 205-a, as described above with respect to FIG. 2. During transmission, the analog signal is upconverted from a baseband frequency to an intermediate or radio frequency and optionally sent to beamformer 235-a, which outputs at least one modulated signal 385 to be transmitted (e.g., by one or more antennas 220 shown in FIG. 2). During reception, at least one modulated signal 385 may be received (e.g., by one or more antennas 220 shown in FIG. 2). The received modulated signal 385 may be processed by optional beamformer 235-a and downconverted using mixer 230-a and one or more signals (e.g., phase flipped signals) from LO generator 225-a which is then sent to logic controller 205-a for further processing and/or decoding. Additional details related to flipping and maintaining the phase of an LO signal are presented below. The foregoing provides just one example relating to high-speed and reliable LO signal phase flipping, and the techniques of the present disclosure are not limited to the discussion of this example. For instance, in other examples, additional circuitry or devices may be utilized to delay and/or maintain the internal state of the frequency divider 350.

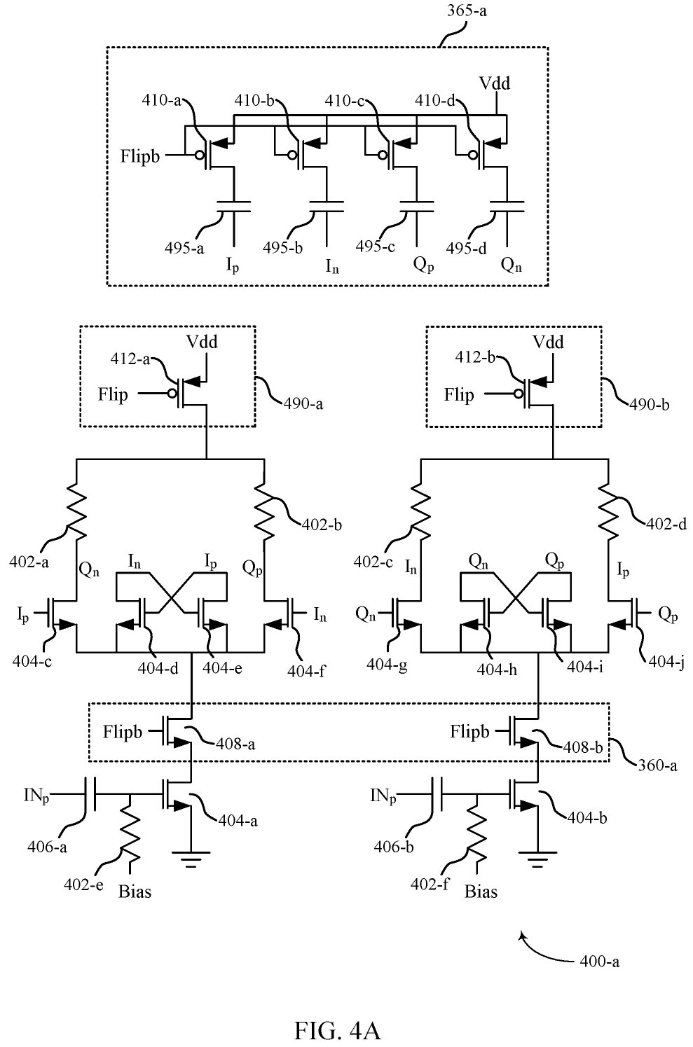

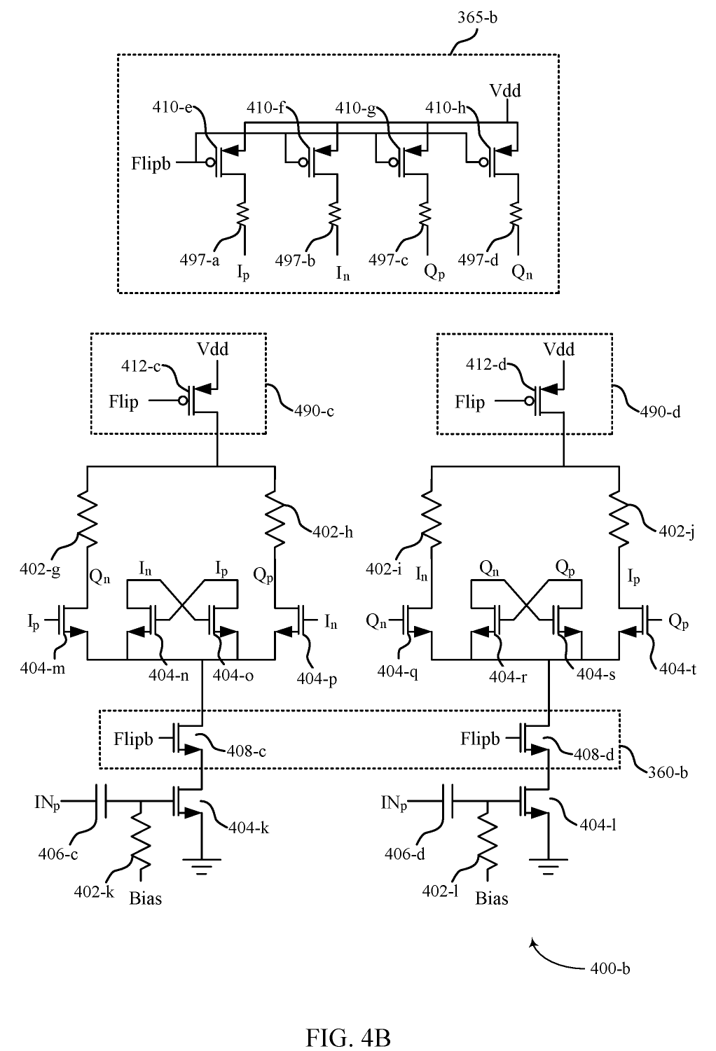

FIGS. 4A and 4B illustrate example circuit diagrams of a local oscillator that supports fast local oscillator phase flipping in accordance with aspects of the present disclosure, which represent examples of the corresponding elements described with reference to FIGS. 1-3. In the example of FIG. 4A, a frequency divider 400-a includes a number of circuit elements such as a pulse swallower 360-a, a storage device 365-a, and power supply cutting switches 490-a and 490-b. Frequency divider 400-a also includes various resistors 402, transistors 404, and capacitors 406. Resistors 402-a, 402-b, 402-c, 402-d, 402-e, and 402-f can be used to determine signal swing, reference voltages and/or control current flowing through frequency divider 400-a. Transistors 404-a, 404-b, 404-c, 404-d, 404-e, 404-f, 404-g, 404-h, 404-i, and 404-j act as switches and are used to direct current through the frequency divider 400-a, while capacitors 406-a and 406-b mitigate direct current (DC) flow into the frequency divider 400-a.

As shown, an oscillator signal (e.g., oscillator signal 380 of FIG. 3) is input into frequency divider 400-a represented by INp. Pulse swallower 360-a includes transistors 408-a and 408-b configured to act as switches that direct or prevent current flow into the frequency divider 400-a. In this example, the transistors 408-a and 408-b are activated by a flipb signal (e.g., a flipb signal generated by flip signal generator 355). In some cases, the pulse swallower 360-a is configured to swallow a current pulse of the input oscillator signal INp and may be activated by an inverted flipb signal (i.e., a flip signal). In other cases, the pulse swallower 360-a is activated by a flipb signal, as shown, which is synchronized with a signal such as the control signal 370 or the oscillator signal 380 of FIG. 3.

The frequency divider 400-a is configured to produce four signals (In, Ip, Qn, Qp), each of which may be output by the frequency divider 400-a to be used in transmission and/or reception, for example. Connected to each of the four signals are capacitors 495-a, 495-b, 495-c, and 495-d of the storage device 365-a. The storage device 365-a is configured to store the internal state of the frequency divider 400-a by delaying decay of the In, Ip, Qn, and Qp signals using the capacitors 495-a, 495-b, 495-c, and 495-d. As shown, the storage device 365-a is activated using a flipb signal acting on transistor switches 410-a, 410-b, 410-c, and 410-d, which are connected to the capacitors 495-a, 495-b, 495-c, and 495-d. Though not shown, the storage device 365-a can be activated by a flip signal or another signal synchronized with a control signal such as the oscillator signal INp input into the frequency divider 400-a.

Also in this example, frequency divider 400-a includes power supply cutting switches 490-a and 490-b that include transistor switches 412-a and 412-b, respectively. The power supply cutting switches 490-a and 490-b are configured to cut power to the frequency divider 400-a using transistor switches 412-a and 412-b that are deactivated by a flip signal and used to delay the decay and/or maintain the internal state of the frequency divider 400-a. In combination with the pulse swallower 360-a and the storage device 365-a, the internal state of the frequency divider 400-a can be stored until a next frequency division after swallowing an input signal INp to the frequency divider 400-a reliably and at a high-speed as there are no additional active circuit elements in the path of the output signals produced by the frequency divider 400-a.

In FIG. 4B, a frequency divider 400-b is shown including a number of circuit elements such as a pulse swallower 360-b, a storage device 365-b, and power supply cutting switches 490-c and 490-d. Frequency divider 400-b also includes various resistors 402, transistors 404, and capacitors 406. Resistors 402-g, 402-h, 402-i, 402-j, 402-k, and 402-l can be used to determine signal swing, reference voltages and/or control current flowing through frequency divider 400-b. Transistors 404-k, 404-l, 404-m, 404-n, 404-o, 404-p, 404-q, 404-r, 404-s, and 404-t act as switches and are used to direct current through the frequency divider 400-b, while capacitors 406-c and 406-d mitigate DC flow into the frequency divider 400-b.

As shown, an oscillator signal (e.g., oscillator signal 380 of FIG. 3) is input into frequency divider 400-b represented by INp. Pulse swallower 360-b includes transistors 408-c and 408-d configured to act as switches that direct or prevent current flow into the frequency divider 400-b. In this example, the transistors 408-c and 408-d are disabled by a flipb signal (e.g., a flipb signal generated by flip signal generator 355) when the flipb signal is low. In some cases, the pulse swallower 360-b is configured to swallow a current pulse of the input oscillator signal INp which is synchronized with a signal such as the control signal 370 or the oscillator signal 380 of FIG. 3.

The frequency divider 400-b is configured to produce four signals (In, Ip, Qn, Qp), each of which may be output by the frequency divider 400-b to be used in transmission and/or reception, for example. Connected to each of the four signals are resistors 497-a, 497-b, 497-c, and 497-d of the storage device 365-b. The storage device 365-b is configured to store the internal state of the frequency divider 400-b by delaying decay of the In, Ip, Qn, and Qp signals using the resistors 497-a, 497-b, 497-c, and 497-d. As shown, the storage device 365-b is activated using a flipb signal when the flipb signal is low acting on transistor switches 410-e, 410-f, 410-g, and 410-g, which are connected to the resistors 497-a, 497-b, 497-c, and 497-d. Though not shown, the storage device 365-b can be activated by a flip signal or another signal synchronized with a control signal such as the oscillator signal INp input into the frequency divider 400-b.

Also in this example, frequency divider 400-b includes power supply cutting switches 490-c and 490-d that include transistor switches 412-c and 412-d, respectively. The power supply cutting switches 490-c and 490-d are configured to cut power to the frequency divider 400-b using transistor switches 412-c and 412-d that are deactivated by a flip signal and used to delay the decay and/or maintain the internal state of the frequency divider 400-b. In combination with the pulse swallower 360-b and the storage device 365-b, the internal state of the frequency divider 400-b can be stored until a next frequency division after swallowing an input signal INp to the frequency divider 400-b reliably and at a high-speed as there are no additional circuit elements in the path of the output signals produced by the frequency divider 400-b.

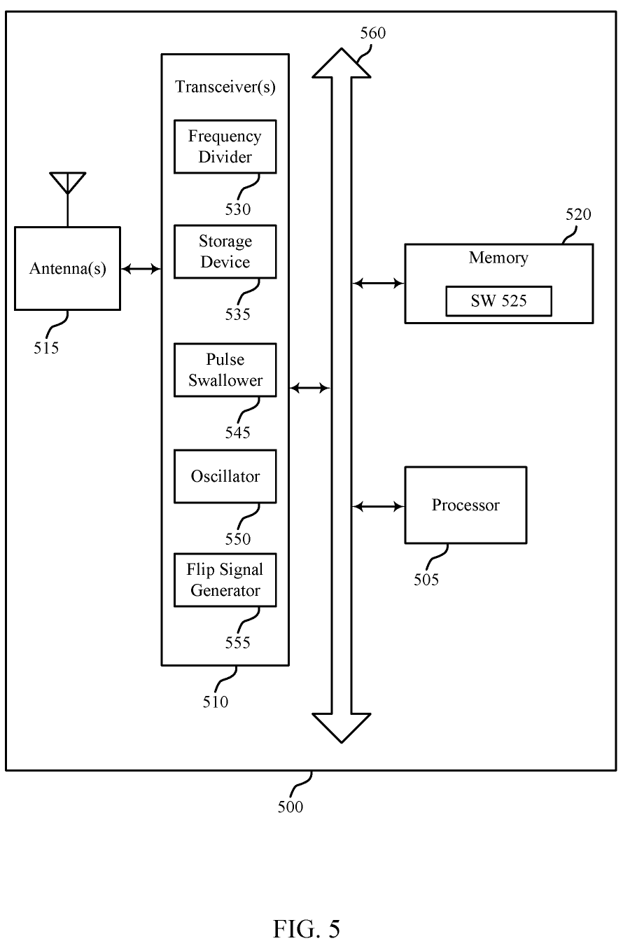

FIG. 5 illustrates a block diagram of an example wireless device, such as a STA or an AP, that supports fast local oscillator phase flipping in accordance with aspects of the present disclosure, and with respect to FIGS. 1-4. Wireless device 500 includes a processor 505, a memory 520, one or more transceivers 510, and one or more antennas 515, each of which is communicatively coupled with a bus 560, which enables communication between the components. The one or more transceivers 510 includes a frequency divider 530, storage device 535, pulse swallower 545, oscillator 550, and flip signal generator 555. The antenna(s) 515 are also communicatively coupled with the one or more transceivers 510.

The processor 505 is an intelligent hardware device, such as a central processing unit (CPU), a microcontroller, an application-specific integrated circuit (ASIC), etc. The processor 505 processes information received through the transceiver(s) 510 and information to be sent to the transceiver(s) 510 for transmission through the antenna(s) 515.

The memory 520 stores computer-readable, computer-executable software (SW) code 525 containing instructions that, when executed, cause the processor 505 or another one of the components of wireless device 500 to perform various functions described herein, for example, implementing phase flipping for a high speed local oscillator.

The transceiver(s) 510 communicate bi-directionally with other wireless devices, such as APs 105, STAs 115, or other devices. The transceiver(s) 510 include a modem to modulate packets and frames and provide the modulated packets to the antenna(s) 515 for transmission. The modem is additionally used to demodulate packets received from the antenna(s) 515.

The transceiver(s) 510 are configured to process analog signals. For instance, analog signals at a baseband frequency are sent to the transceiver(s) 510 and various components (e.g., frequency divider 530, storage device 535, pulse swallower 545, oscillator 550, and flip signal generator 555) of the transceiver(s) 510 can be used to process the baseband analog signals. For example, using a mixer (e.g., mixer 230) and LO generator (e.g., LO generator 225), the analog signals are modulated and upconverted (during transmission) or downconverted (during reception) to generate a modulated radio signal. If beamforming is to be performed, the modulated radio signal can then be further processed by a beamformer (e.g., beamformer 235), which generates and routes multiple signals to each of the antenna(s) 515.

The frequency divider 530, storage device 535, pulse swallower 545, oscillator 550, and flip signal generator 555 implement the features described with reference to FIGS. 1-4, as further explained below.

FIG. 5 shows just one possible implementation of a device implementing the features of FIGS. 1-4. While the components of FIG. 5 are shown as discrete hardware blocks (e.g., ASICs, field programmable gate arrays (FPGAs), semi-custom integrated circuits, etc.) for purposes of clarity, it will be understood that each of the components may also be implemented by multiple hardware blocks adapted to execute some or all of the applicable features in hardware. Alternatively, features of two or more of the components of FIG. 5 may be implemented by a single, consolidated hardware block. For example, a single transceiver 510 chip may implement the processor 505, memory 520, frequency divider 530, storage device 535, pulse swallower 545, oscillator 550, and flip signal generator 555.

In still other examples, the features of each component may also be implemented, in whole or in part, with instructions embodied in a memory, formatted to be executed by one or more general or application-specific processors.

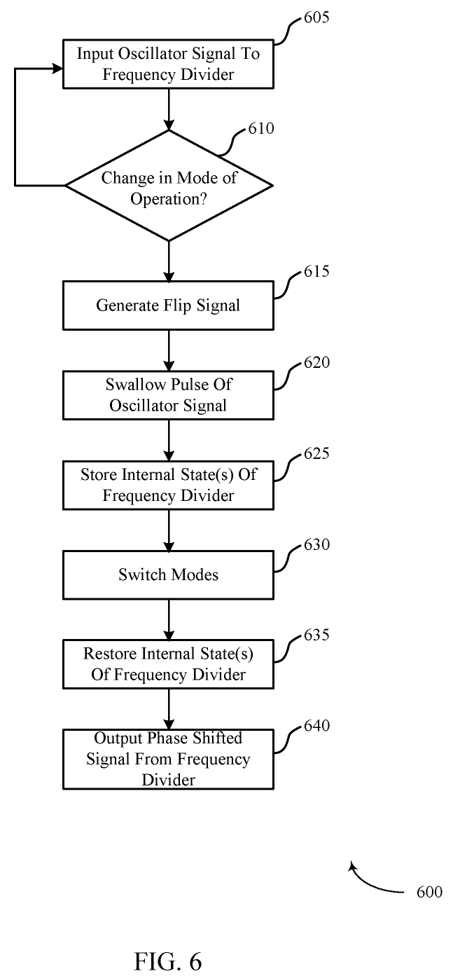

FIG. 6 shows a flowchart illustrating an example method 600 for fast local oscillator phase flipping in accordance with various aspects of the present disclosure. The method 600 may be performed by any of the STAs 115 or APs 105 discussed in the present disclosure, but for clarity the method 600 will be described from the perspective of the wireless device 500 of FIG. 5. Broadly speaking, the method 600 illustrates a procedure by which a wireless device 500 introduces a phase shift to an output of local oscillator signal by storing an internal state of the frequency divider, swallowing a signal pulse with a synchronization mechanism, or cutting a power supply, prior to switching between wireless communication modes of operation.

The method 600 begins at 605 with inputting a signal generated by an oscillator (e.g., oscillator 550 of FIG. 5), into a frequency divider (e.g., frequency divider 530 of FIG. 5). The signal generated by the oscillator 550 may repeat at a frequency (e.g., 2 GHz, 13 GHz, etc.) that is inherently produced by providing a voltage to the oscillator 550. Frequency divider 530 produces an in-phase and a quadrature signal (e.g., a signal that is 90 degrees out of phase with the other) that are associated with an integer divisor (e.g., ½, ¼, etc.) of the frequency generated at the oscillator 550. As discussed above, when the operating mode of wireless device 500 changes, the phase of the signals output by the frequency divider 530 can be misaligned due to the initial states of the frequency divider 530. In some cases, frequency divider 530 is a current mode divider and is coupled to the oscillator 550.

Accordingly, at 610, wireless device 500 monitors for an upcoming change in the mode of operation. If wireless device 500 does not observe a change in the mode of operation, wireless device 500 returns to 605. Alternatively, if wireless device 500 observes a change or upcoming change in the mode of operation, wireless device 500 proceeds to 610. In some examples, wireless device 500 detects a change in the mode of operation based at least in part on a received WLAN preamble. For instance, the wireless device 500 may determine a change in operating mode has occurred based at least in part on receiving a very high throughput short training field (VHT-STF).

At 615, if wireless device 500 determines that the phases of the frequency divider 530 are misaligned, the flip signal generator 555 of FIG. 5 generates a phase flip signal. In some cases, the flip signal generator 555 generates a flip signal and/or a flipb signal, where the flipb signal is an inverted version of the flip signal.

At 620, the flip signal is used to facilitate the swallowing of a pulse of the oscillator signal. For instance, flip signal generator 555 synchronizes the flip signal and/or flipb signal with the oscillator signal and inputs the flip and/or flipb signal to a switching device used to swallow a pulse of the oscillator signal—e.g., a current pulse swallow switch connected to an input of the divider. The pulse of the oscillator signal can be swallowed after inputting the pulse of the oscillator signal to the frequency divider.

After swallowing the pulse of the oscillator signal, storage device 535 of FIG. 5 is used to store the internal states of the frequency divider 530 at 625. Storage device 535 is used to delay the decay of the internal state of the frequency divider 530. In one example, the states of the frequency divider 530 are maintained until a next frequency division of the oscillator 550. Various embodiments may be implemented to maintain the internal states of the frequency divider 530. For instance, a switching device (e.g., a cutting switch) can be placed at an input of the frequency divider, a switching device can be placed to a power supply, or a switchable capacitor bank can be utilized, a switchable resistor bank, or any combination thereof. In some cases, one or more of the switching devices are activated using the flip and/or flipb signal. In some examples, storage device 535 is implemented using the switchable capacitor bank, the switchable resistor bank, or both.

At 630, the wireless device 500 switches operating modes. For instance, wireless device 500 can switch from a first operating mode that supports reception of 80 MHz bandwidth signals to a second operating mode that supports reception of 160 MHz bandwidth signals. After switching modes, the internal states of the frequency divider 530 may be restored at 635. For instance, by de-asserting the flip and/or flipb signal to the one or more switching devices. After restoring the internal states of the frequency divider 530, frequency divider 530 outputs a phase shifted signal (e.g., 180 degree phase shift) with respect to the signal output by frequency divider 530 prior to the change in the mode of operation at 640.

It should be noted that these methods describe possible implementation, and that the operations and the steps may be rearranged or otherwise modified such that other implementations are possible. In some examples, aspects from two or more of the methods may be combined. For example, aspects of each of the methods may include steps or aspects of the other methods, or other steps or techniques described herein. Thus, aspects of the disclosure may provide for fast local oscillator phase flipping.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not to be limited to the examples and designs described herein but is to be accorded the broadest scope consistent with the principles and novel features disclosed herein.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different PHY locations. Also, as used herein, including in the claims, “or” as used in a list of items (for example, a list of items prefaced by a phrase such as “at least one of” or “one or more”) indicates an inclusive list such that, for example, a list of at least one of A, B, or C means A or B or C or AB or AC or BC or ABC (i.e., A and B and C).

The wireless communications system or systems described herein may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. The techniques described herein may be used for either synchronous or asynchronous operations.

Thus, aspects of the disclosure may provide for fast local oscillator phase flipping. It should be noted that these methods describe possible implementations, and that the operations and the steps may be rearranged or otherwise modified such that other implementations are possible. In some examples, aspects from two or more of the methods may be combined.

Some of the various illustrative blocks and modules described in connection with the disclosure herein may be implemented or performed with a general-purpose processor, a digital signal processor (DSP), an ASIC, an field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Thus, the functions described herein may be performed by one or more other processing units (or cores), on at least one integrated circuit (IC). In various examples, different types of ICs may be used (e.g., Structured/Platform ASICs, an FPGA, or another semi-custom IC), which may be programmed in any manner known in the art. The functions of some units may also be implemented, in whole or in part, with instructions embodied in a memory, formatted to be executed by one or more general or application-specific processors.

1. A method of wireless communication comprising:
inputting an oscillator signal into a frequency divider;
activating storage circuitry via a flip signal or an inverted flip signal synchronized with the oscillator signal;
storing a state of the frequency divider based at least in part on the flip signal or the inverted flip signal; and
outputting a phase shifted version of the oscillator signal based at least in part on the stored state of the frequency divider.

2. The method of claim 1, further comprising:
swallowing a pulse of the oscillator signal, wherein outputting the phase shifted version of the oscillator signal is based at least in part on the swallowed pulse.

3. The method of claim 2, wherein swallowing the pulse of the oscillator signal comprises:
swallowing a current pulse of the oscillator signal after inputting the oscillator signal into the frequency divider.

4. The method of claim 3, wherein swallowing the current pulse comprises:
activating a current pulse swallow switch using the flip signal or the inverted flip signal synchronized with the oscillator signal.

5. The method of claim 1, wherein storing the state of the frequency divider comprises:
delaying decay of the state of the frequency divider.

6. The method of claim 5, wherein delaying the decay comprises:
delaying the decay of the state using at least one selected from the group consisting of a switchable capacitor bank, a switchable resistor bank, and a cutting switch connected to an input of the frequency divider.

7. The method of claim 6, further comprising:
activating the at least one selected from the group consisting of the switchable capacitor bank, the switchable resistor bank, and the cutting switch using the flip signal or the inverted flip signal.

8. The method of claim 1, wherein storing the state of the frequency divider comprises:
maintaining the state of the frequency divider until a next frequency division.

9. The method of claim 8, wherein maintaining the state of the frequency divider comprises:
activating a cutting switch connected to an input of the frequency divider, activating a cutting switch connected to a power supply, or activating a switchable capacitor bank.

10. The method of claim 9, wherein the cutting switch connected to the input of the frequency divider, the cutting switch connected to the power supply, or the switchable capacitor bank is activated using the flip signal or the inverted flip signal.

11. The method of claim 1, wherein the frequency divider is coupled to a local oscillator configured to generate the oscillator signal.

12. The method of claim 1, wherein the frequency divider is a current mode divider.

13. The method of claim 1, further comprising:
switching from a first wireless communication mode to a second wireless communication mode; and preserving the state of the frequency divider prior to switching between the first and second wireless communication modes.

14. The method of claim 13, further comprising:
restoring the preserved state of the frequency divider after switching between the first and second wireless communication modes.

15. A communications device for wireless communication, comprising:
an oscillator;
frequency divider to receive an oscillator signal from the oscillator, wherein the frequency divider includes storage circuitry configured to store a state of the frequency divider, the storage circuitry being activated via a flip signal or an inverted flip signal synchronized with the oscillator signal, and wherein the frequency divider outputs a phase shifted version of the oscillator signal based at least in part on the stored state of the frequency divider.

16. The communications device of claim 15, wherein the frequency divider comprises:
a pulse swallower configured to swallow a pulse of the oscillator signal, wherein the phase shifted version of the oscillator signal is output based at least in part on the swallowed pulse.

17. The communications device of claim 16, wherein the pulse of the oscillator signal comprises a current pulse.

18. The communications device of claim 17, wherein the pulse swallower comprises a current pulse swallow switch activated by the flip signal or an inverted flip signal synchronized with the oscillator signal.

19. The communications device of claim 15, wherein the storage circuitry stores the state of the frequency divider by delaying a decay of an internal state of the frequency divider.

20. The communications device of claim 19, wherein the storage circuitry comprises at least one selected from the group consisting of a switchable capacitor bank, a switchable resistor bank, and a cutting switch connected to an input of the frequency divider.

21. The communications device of claim 20, wherein the one or more of the group of the switchable capacitor bank, the switchable resistor bank, and the cutting switch is activated using the flip signal or the inverted flip signal.

22. The communications device of claim 15, wherein the storage circuitry stores the state of the frequency divider by maintaining the state until a next frequency division.

23. The communications device of claim 20, wherein the storage circuitry maintains the state of the frequency divider when at least one from the group consisting of:
a cutting switch connected to the input of the frequency divider, a cutting switch connected to a power supply, and the switchable capacitor bank is activated.

24. The communications device of claim 23, wherein the cutting switch connected to the input of the frequency divider, the cutting switch connected to the power supply, or the switchable capacitor bank is activated using the flip signal or the inverted flip signal.

25. The communications device of claim 15, wherein the frequency divider is a current mode divider.

26. The communications device of claim 15, further comprising:
a transceiver configured to switch from a first wireless communication mode to a second wireless communication mode, wherein the transceiver comprises storage circuitry configured to store the state of the frequency divider prior to switching between the first and second wireless communication modes.

27. The communications device of claim 26, wherein the storage circuitry restores the preserved state of the frequency divider to the frequency divider after switching between the first and second wireless communication modes.

28. A communications device for wireless communication comprising:
means for inputting an oscillator signal into a frequency divider;
means for activating storage circuitry via a flip signal or an inverted flip signal synchronized with the oscillator signal;
means for storing a state of the frequency divider based at least in part on the flip signal or the inverted flip signal; and
means for outputting a phase shifted version of the oscillator signal based at least in part on the stored state of the frequency divider.

29. The communications device of claim 28, further comprising:
means for swallowing a pulse of the oscillator signal, wherein outputting the phase shifted version of the oscillator signal is based at least in part on the swallowed pulse.

30. The communications device of claim 29, wherein the means for swallowing the pulse comprises:
means for swallowing a current pulse of the oscillator signal after inputting the oscillator signal into the frequency divider; and
means for activating a current pulse swallow switch using the flip signal or the inverted flip signal synchronized with the oscillator signal.
